(19) United States
(12) Patent Application Publication
(10) Pub. No.: US 2018/0182732 A1
(43) Pub. Date: Jun. 28, 2018

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventor: Makoto IMAI, Suwa-city (JP)

(21) Appl. No.: 15/826,708

(22) Filed: Nov. 30, 2017

(30) Foreign Application Priority Data
Dec. 28, 2016 (JP) 2016-257135

(51) Int. Cl. H01L 23/00; H01L 23/31; H01L 23/495; H01L 21/48; H01L 21/56

(52) U.S. Cl. CPC H01L 24/49; H01L 23/3114; H01L 23/49513; H01L 2224/49052; H01L 23/49541; H01L 21/4825; H01L 21/565; H01L 23/4952

(57) ABSTRACT

Provided is a semiconductor device comprising; a semiconductor chip, a first electrode pair, a first wire group that has a plurality of bonding wires connecting electrodes of the first electrode pair in parallel, and a sealing portion that mold-seals said elements, wherein the plurality of bonding wires belonging to the first wire group are wired such that length of each of the bonding wires on a far side in a first direction parallel with an in-plane direction of the semiconductor chip is longer than length of each of the bonding wires on a near side, and each height at respective positions of each of the bonding wires on the far side in the first direction is not lower than each height at respective positions, corresponding to the respective positions of each of the bonding wires on the far side, of each of the bonding wires on the near side.

The contents of the following Japanese patent application are incorporated herein by reference:
NO. 2016-257135 filed in JP on Dec. 28, 2016.

### BACKGROUND

### 1. Technical Field

The present invention relates to a semiconductor device and a method for manufacturing semiconductor device.

### 2. Related Art

Conventionally, techniques for preventing wires from coming into contact with each other due to injection of a sealing material in a semiconductor package in which electrode pairs that are different from each other are densely arranged have been proposed (see, for example, Patent Documents 1 to 3).

Patent Document 1: Japanese Patent Application Publication No. 2008-103685

Patent Document 2: Japanese Translation of PCT International Patent Application No. 2005-532672

Patent Document 3: Japanese Patent Application Publication No. 2011-3764

It has been considered to connect both electrodes in parallel by a plurality of wires when flowing a large current between the same electrode pair, however, the conventional techniques do not correspond to such a connecting form.

### SUMMARY

An object of one aspect the technological innovation included herein is to provide a semiconductor device and a method for manufacturing semiconductor device that can solve the above problem. The above and other objects can be achieved by combinations of characteristics described in the claims. That is, in a first aspect of the present invention, there is provided a semiconductor device comprising a semiconductor chip, a first electrode pair, a first wire group that has a plurality of bonding wires that connect electrodes of the first electrode pair electrically in parallel, and a sealing portion that mold-seals the semiconductor chip, the first electrode pair, and the first wire group, wherein the plurality of bonding wires belonging to the first wire group are wired such that length of each of the bonding wires on the far side in a first direction that is parallel with an in-plane direction of the semiconductor chip is longer than length of each of the bonding wires on the near side, and each height at respective positions of each of the bonding wires on the far side in the first direction is not lower than each height at respective positions, corresponding to the respective positions of each of the bonding wires on the far side, of each of the bonding wires on the near side.

In a second aspect of the present invention, there is provided a method for manufacturing semiconductor device comprising; a fixing step in which relative positions of electrodes of a first electrode pair are fixed, a connecting step in which a first wire group including a plurality of bonding wires connects electrodes of the first electrode pair electrically in parallel, a sealing step in which a molding material is injected into a molding mold housing a semiconductor chip, the first electrode pair, and the first wire group from a first direction and sealing them, wherein the plurality of bonding wires belonging to the first wire group are wired such that length of each of the bonding wires on the far side in a first direction is longer than length of each of the bonding wires on the near side, and each height at respective positions of each of the bonding wires on the far side in the first direction is not lower than each height at respective positions, corresponding to the respective positions of each of the bonding wires on the far side, of each of the bonding wires on the near side.

The summary clause does not necessarily describe all necessary features of the embodiments of the present invention. The present invention may also be a sub-combination of the features described above.

### BRIEF DESCRIPTION OF THE DRAWINGS

FIG. 1 is a diagram showing a semiconductor device according to this embodiment.

FIG. 2 is a diagram showing a plurality of bonding wires belonging to a first wire group when the semiconductor device is seen from a near side of a first direction.

FIG. 3 is a diagram showing a method for manufacturing the semiconductor device according to this embodiment.

FIG. 4 is a diagram showing the semiconductor device in a state where a connecting step is performed.

FIG. 5 is a diagram showing one example of the plurality of bonding wires belonging to the first wire group when the semiconductor device in the state where the connecting step is performed is seen from the near side of the first direction.

### DESCRIPTION OF EXEMPLARY EMBODIMENTS

Hereinafter, (some) embodiment(s) of the present invention will be described. The embodiment(s) do(es) not limit the invention according to the claims. Also, all the combinations of the features described in the embodiment(s) are not necessarily essential to means provided by aspects of the invention.

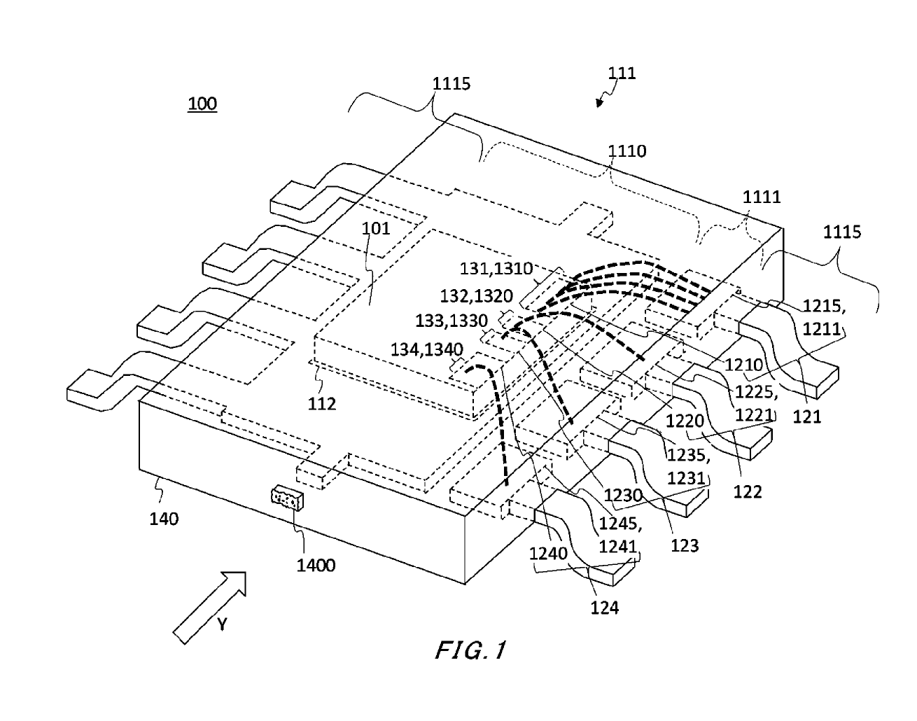

FIG. 1 is a diagram showing a semiconductor device 100 according to this embodiment. The semiconductor device 100 is a semiconductor package, and has a flat dimension of 5 mm×5 mm or 8 mm×8 mm as one example. The semiconductor device 100 comprises a semiconductor chip 101, a leadframe 111, a first electrode pair 121 to a fourth electrode pair 124, a first wire group 131 to a fourth wire group 134, and a sealing portion 140.

The semiconductor chip 101 is a chip that has one or more semiconductor elements. In this embodiment, as one example, the semiconductor chip 101 may be a single-function discrete chip that has one type of element such as a transistor, a diode, a capacitor, or a thyristor, or may be a multi-function chip that includes an IC circuit or the like. The semiconductor chip 101 may be arranged on the leadframe 111.

The leadframe 111 is a member that supports the semiconductor chip 101. The leadframe 111 may have a leadframe body 1110, a plurality of leadframe segments 1111, and a plurality of external terminals 1115.

The leadframe body 1110 is formed in a rectangular plate shape, and supports the semiconductor chip 101 on an upper surface of a center part. A solder 112 may be interposed between the semiconductor chip 101 and the leadframe body 1110.

The plurality of leadframe segments 1111 are respectively formed in a plate shape, and may be spaced away from each other and be arranged being spaced away from the leadframe body 1110. The plurality of leadframe segments 1111 may be arranged in the same surface as the leadframe body 1110 as one example.

The plurality of external terminals 1115 are terminals exposed to outside of the sealing portion 140 described later. In this embodiment, as one example, some of the plurality of external terminals 1115 may be integrated with the leadframe body 1110, and the others may be respectively integrated with the plurality of leadframe segments 1111.

The plurality of external terminals 1115 may be power supply terminals, ground terminals, or signal terminals of the semiconductor device 100. Here, the power supply terminal may be a terminal through which a current from a power supply which is not illustrated or a current to the power supply flows. When there are a plurality of terminals in the semiconductor device 100, the power supply terminal may be a terminal that has a larger amount of the current flowing than those of other terminals. The signal terminal may be a terminal that performs input/output of a control signal or the like.

Note that the leadframe 111 may be formed of a metal (copper as one example) or the like that has excellent heat dissipation and conductivity. For example, the leadframe 111 may be formed by pressing a metal plate.

The first electrode pair 121 to the fourth electrode pair 124 are electrode pairs that are different from each other. The first electrode pair 121 to the fourth electrode pair 124 may have electrodes that are respectively arranged being spaced away from each other in a first direction Y and are respectively spaced away seen from the first direction Y (in this embodiment, spaced away in the left-to-right direction seen from the first direction Y).

The first electrode pair 121 has electrodes 1210, 1211. The electrode 1210 may be included in the semiconductor chip 101, or may be provided in the semiconductor chip 101. For example, the electrode 1210 may be exposed on an upper surface of the semiconductor chip 101. The electrode 1210 may be a power supply electrode or a ground electrode of the semiconductor chip 101.

Alternatively, the electrode 1210 may be provided on the leadframe 111 and be connected to terminals on the upper surface or on a lower surface of the semiconductor chip 101. For example, the electrode 1210 may be connected to a terminal on the lower surface of the semiconductor chip 101 via a wiring pattern (not shown) that is formed of an insulating layer and a conductive layer on the leadframe body 1110.

The electrode 1211 may be included in the first conductor 1215, or may be provided on the first conductor 1215. For example, the electrode 1211 may be exposed on an upper surface of the first conductor 1215. The first conductor 1215 may be any one of the plurality of leadframe segments 1111. The external terminal 1115 integrated with the leadframe segment 1111 may be a power supply terminal or a ground terminal of the semiconductor device 100. Note that the electrode 1211 may be provided in the semiconductor chip 101 with the electrode 1210.

Similarly to the first electrode pair 121 described above, the second electrode pair 122 has an electrode 1220 and an electrode 1221, the third electrode pair 123 has an electrode 1230 and an electrode 1231, the fourth electrode pair 124 has an electrode 1240 and an electrode 1241, respectively. The electrodes 1220, 1230, and 1240 may be provided in the semiconductor chip 101, and the electrodes 1221, 1231, and 1241 may be provided in the second conductor 1225, the third conductor 1235, and the fourth conductor 1245, respectively. The second conductor 1225, the third conductor 1235, and the fourth conductor 1245, respectively, may be any one of the plurality of leadframe segments 1111.

The first wire group 131 to the fourth wire group 134 are wire groups that are different from each other, and may connect separate electrode pairs.

The first wire group 131 connects the electrodes 1210, 1211 of the first electrode pair 121 electrically in parallel. The first wire group 131 has a plurality of (in this embodiment, four as one example) bonding wires 1310. By connecting the electrodes 1210, 1211 in parallel by the plurality of bonding wires 1310 in this way, it is possible to maintain the current capacity between the electrodes 1210, 1211 large while reducing the wire diameter of each bonding wire 1310. The wire diameter of the bonding wire 1310 may be smaller than or equal to 50 μm, as one example, 18 μm, 20 μm, or the like. Note that if adjacent bonding wires 1310 come into contact with each other, the impedance or the like can vary from the designed value. Because of this, in this embodiment, bonding wires 1310 may be in a non-contact state in view of maintaining the operating characteristics.

In order to make bonding wires 1310 non-contact with each other, length of each of the plurality of bonding wires 1310 on the far side in the first direction Y that is parallel with an in-plane direction of the semiconductor chip 101 is longer than length of each of the plurality of bonding wires 1310 on the near side. Also, the plurality of bonding wires 1310 are wired such that each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. Details of the first direction Y will be described later. Here, each point of the bonding wire 1310 may be each point of a middle part of the bonding wire 1310, except end parts. Also, each corresponding point of the bonding wire 1310 may be, for example, a point where a ratio of a wiring length from one end/a total length is equal to those of other bonding wires 1310.

At least one of the plurality of bonding wires 1310, as one example, each of the plurality of bonding wires 1310 may be tilted toward the far side of the first direction Y as a result of, for example, a molding material of the sealing portion 140 having been injected along the first direction Y. For example, the plurality of bonding wires 1310 may be formed in an arc-shape that heads toward the far side of the first direction Y in accordance with being separated from a connecting point relative to the first electrode pair 121.

Each connecting point of the bonding wire 1310 relative to the electrode 1210 may be lined up along the first direction Y, or may be separated from a connecting point relative to the electrode 1211 as heading from the near side to the far side of the first direction Y. Similarly, each connecting point of the bonding wire 1310 relative to the electrode 1211 may be lined up along the first direction Y, or may be separated from a connecting point relative to the electrode 1210 as heading from the near side to the far side of the first direction Y. Each connecting point of the bonding wire 1310 relative to the electrode 1210 and each connecting point of the bonding wire 1310 relative to the electrode 1211 may be arranged being spaced away from each other in the left-to-right direction seen from the first direction Y. Also, each connecting point of the bonding wire 1310 relative to the electrodes 1210, 1211 may be arranged at a regular interval. For example, an interval between the connecting points of each bonding wire 1310 in the first direction Y may be equal to or greater than the wire diameter (as one example, 18 μm, 20 μm, or the like), and may be smaller than or equal to 2 mm or 1 mm. By increasing the interval between the connecting points, the operating characteristics are prevented from varying due to that the contact state between the bonding wires 1310 varies by aged deterioration, temperature conditions or the like. Also, by reducing the interval between the connecting points, it is possible to make the semiconductor device 100 smaller.

The bonding wire 1310 may be formed of conductive metal such as gold, silver, copper, or aluminum. Note that in this embodiment, as one example, the electrodes 1210, 1211 of the first electrode pair 121 are wire-bonded only by the plurality of bonding wires 1310 of the first wire group 131.

Each of the second wire group 132 to the fourth wire group 134 has each of one bonding wire 1320 to one bonding wire 1340 that electrically connects each of electrodes of the second electrode pair 122 to electrodes of the fourth electrode pair 124, respectively. The bonding wires 1320 to 1340 may be wires similar to the bonding wire 1310. At least one of these bonding wires 1320 to 1340, as one example, each of these bonding wires 1320 to 1340 may be tilted toward the far side of the first direction Y as a result of, for example, a molding material of the sealing portion 140 having been injected along the first direction Y. For example, the bonding wires 1320 to 1340 may be formed in an arc-shape that heads toward the far side of the first direction Y in accordance with being separated from the connecting points relative to the electrode pairs 122 to 124.

The sealing portion 140 mold-seals the semiconductor chip 101, the leadframe 111, the first electrode pair 121 to the fourth electrode pair 124, and the first wire group 131 to the fourth wire group 134, or the like. The sealing portion 140 may be formed of solidified resin. As the resin, insulative thermosetting resin such as, for example, epoxy resin, maleimide resin, polyimide resin, isocyanate resin, amino resin, phenol resin, silicone based resin, or the like may be used. An additive such as inorganic filler may be contained in the resin.

In this embodiment, as one example, the sealing portion 140 has a rectangular shape seen from the first direction Y. The sealing portion 140 may have another shape such as a rhomboidal shape. The sealing portion 140 may have an injection trace 1400 of a molding material at an end part on the near side of the first direction Y. For example, the sealing portion 140 may have the injection trace 1400 or a discharge trace (not shown) of the molding material at respective end parts on the near side and on the far side of the first direction Y. In other words, the first direction Y may be a direction that heads from the side closer to the injection trace 1400 to the side far from the injection trace 1400, and may be, for example, a direction that heads from the injection trace 1400 to the discharge trace.

Here, the injection trace 1400 of the molding material may be a trace where a molding material solidified at a gate portion of a forming mold is cut and removed after injecting the molding material into the forming mold and forming the sealing portion 140, and thus the semiconductor device 100. Also, the discharge trace of the molding material may be a trace where the molding material solidified at a suction port for evacuating inside the forming mold is cut and removed. In this embodiment, the injection trace 1400 and the discharge trace may be a shape surrounded by a saw-toothed contour or a distorted contour, and may be an approximately circular shape or a polygonal shape. An area of the discharge trace may be smaller than an area of the injection trace 1400. As a result of an interior of the solidified molding material being exposed, surfaces of the injection trace 1400 and the discharge trace may have larger surface roughness than those of surfaces of other regions in the sealing portion 140.

According to the semiconductor device 100 described above, the plurality of bonding wires 1310, which connect the first electrode pair 121 in parallel, are wired such that length of each of the bonding wires 1310 on the far side in the first direction Y that is parallel with the in-plane direction of the semiconductor chip 101 is longer than length of each of the bonding wires 1310 on the near side, and each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. Thus, it is possible to prevent adjacent bonding wires 1310 in the first direction Y from coming into contact with each other within the sealing portion 140 due to aged deterioration or the like, and to maintain the operating characteristics.

Also, even if at least one of the plurality of bonding wires 1310 is tilted toward the far side of the first direction Y, the wire is made to enter below the bonding wire 1310 on the far side without coming into contact with it. Thus, it is possible to surely prevent adjacent bonding wires 1310 from coming into contact with each other.

Also, because the sealing portion 140 has the injection trace 1400 of the molding material at an end part on the near side of the first direction Y, for example, has the injection trace 1400 or the discharge trace (not shown) of the molding material at respective end parts on the near side and on the far side of the first direction Y, the first direction Y is a direction that heads from the side closer to the injection trace 1400 to the side far from the injection trace 1400. Thus, at a time when injecting the molding material into the forming mold in order to form the semiconductor device 100, when the short bonding wire 1310 on the near side of the first direction Y is tilted toward the side of the long bonding wire 1310 on the far side, the short bonding wire 1310 enters below the bonding wire 1310 on the far side without coming into contact with it. Thus, it is possible to surely prevent adjacent bonding wires 1310 from coming into contact with each other.

Also, because the electrode 1210 of the first electrode pair 121 is provided in the semiconductor chip 101 and the electrode 1211 is provided in the first conductor 1215, the operating characteristics tend to vary due to the contact of bonding wires 1310 with each other. Even in such a case, because it is possible to prevent bonding wires 1310 from coming into contact with each other, by connecting the first electrode pair 121 in parallel by the plurality of bonding wires 1310 as described above, the operating characteristics can be maintained.

Also, because the electrode 1210 of the first electrode pair 121 is a power supply electrode or a ground electrode of the semiconductor chip 101, its amount of the current is large. Even in such a case, by connecting the electrode 1210 and the electrode 1211 in parallel by the plurality of bonding wires 1310 as described above, the current capacity between the first electrode pair 121 can be made larger.

Note that in the above-described embodiment, the first conductor 1215 has been described as a leadframe segment 1111 integrated with the external terminal 1115, and the first conductor 1215 and the external terminal 1115 may be separate.

Also, the semiconductor device 100 has been described to comprise the second electrode pair 122 to the fourth electrode pair 124 and the leadframe 111, and may not comprise at least some of these. Also, an description of connection between the semiconductor chip 101 and the external terminal 1115 integrated with the leadframe body 1110 (the external terminal 1115 on the left side in the diagram) is omitted, and for example, the connection may be in such a way so as to be line symmetric or point symmetric relative to the connection by the first wire group 131 to the fourth wire group 134 shown on the right side in the diagram.

Also, the first electrode pair 121 has been described as being wire-bonded only by the plurality of bonding wires 1310 of the first wire group 131, and may be further wire-bonded by wire different from the bonding wire 1310. Also, the first electrode pair 121 may be connected in parallel by a plurality of first wire groups 131 that respectively have a plurality of bonding wires 1310. In these cases, in order to surely prevent wires from coming into contact with each other, the first wire group 131 may be arranged being spaced away from other wires or other first wire groups 131 with a larger interval than the interval between the bonding wires 1310 within the first wire group 131.

Also, the second wire group 132 to the fourth wire group 134 have been described as respectively having one bonding wire 1320 to 1340. Any of these groups may have a plurality of parallel bonding wires, and any of wire groups that connect the semiconductor chip 101 and the external terminals 1115 integrated with the leadframe body 1110 (the external terminals 1115 on the left side in the diagram) in such a way as to be symmetric with the second wire group 132 to the fourth wire group 134 may have a plurality of bonding wires. For example, the second wire group 132 may have a plurality of bonding wires 1320. These bonding wires 1320, similarly to the bonding wire 1310, may be wired such that length of each of the bonding wires 1320 on the far side in the first direction Y is longer than length of each of the bonding wires 1320 on the near side, and each height at respective positions of each of the bonding wires 1320 on the far side in the first direction Y is not lower than each height at respective positions, corresponding to the respective positions of each of the bonding wires 1320 on the far side, of each of the bonding wires 1320 on the near side. In this case, it is possible to prevent bonding wires 1320 from coming into contact with each other, and to maintain the operating characteristics.

Here, when each bonding wire of the plurality of wire groups connects electrodes spaced away seen from the first direction Y electrically in parallel, in all the wire groups that connect the electrodes in parallel, the plurality of bonding wires may be wired such that length of each of the bonding wires on the far side in the first direction Y is longer than length of each of the bonding wires on the near side, and each height at respective positions of each of the bonding wires on the far side in the first direction Y is not lower than each height at respective positions, corresponding to the respective positions of each of the bonding wires on the far side, of each of the bonding wires on the near side. For example, when the plurality of first wire groups 131 connect the electrodes 1210, 1211 of the first electrode pair 121 in parallel, in all the first wire groups 131, the plurality of bonding wires 1310 may be wired such that length of each of the bonding wires 1310 on the far side in the first direction Y is longer than length of each of the bonding wires 1310 on the near side, and each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. Also, when the first wire group 131 connects the electrodes 1210, 1211 of the first electrode pair 121 in parallel and the second wire group 132 connects the electrodes 1220, 1221 of the second electrode pair 122 in parallel, in the first wire group 131 and the second wire group 132, the plurality of bonding wires 1310, 1320 may be wired such that length of each of the bonding wires 1310, 1320 on the far side in the first direction Y is longer than length of each of the bonding wires 1310, 1320 on the near side, and each height at respective positions of each of the bonding wires 1310, 1320 on the far side in the first direction Y is not lower than each height at respective positions, corresponding to the respective positions of each of the bonding wires 1310, 1320 on the far side, of each of the bonding wires 1310, 1320 on the near side. In such a case, it is possible to maintain the current capacity between electrodes large while reducing the wire diameter of the bonding wire within each wire group, and to prevent bonding wires from coming into contact with each other.

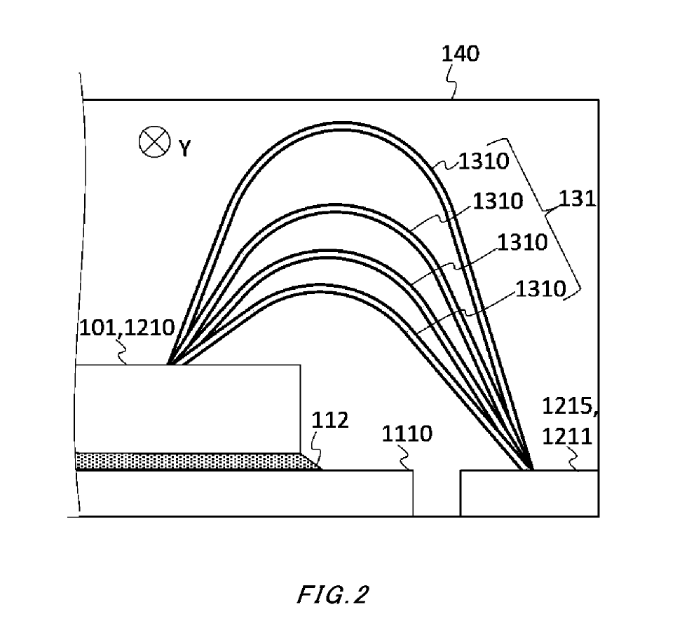

FIG. 2 is a diagram showing a plurality of bonding wires 1310 of a first wire group 131 when the semiconductor device 100 is seen from a near side of a first direction Y.

As shown in this diagram, a plurality of bonding wires 1310 may be wired such that heights of the plurality of bonding wires 1310 relative to a surface of the semiconductor chip 101 increase stepwise from the near side toward the far side in the first direction Y. For example, a difference in loop height between adjacent bonding wires 1310 among the plurality of bonding wires 1310 may be equal to or greater than half of a diameter (that is, a wire diameter) of the bonding wires 1310. As one example, when the wire diameter of each bonding wire 1310 is 20 μm, a difference in loop height between the adjacent bonding wires 1310 may be equal to or greater than 10 μm. Thus, it is possible to surely prevent adjacent bonding wires 1310 from coming into contact with each other. However, in view of reducing a material cost of the bonding wires 1310, the difference in level between the adjacent bonding wires 1310 is preferably smaller.

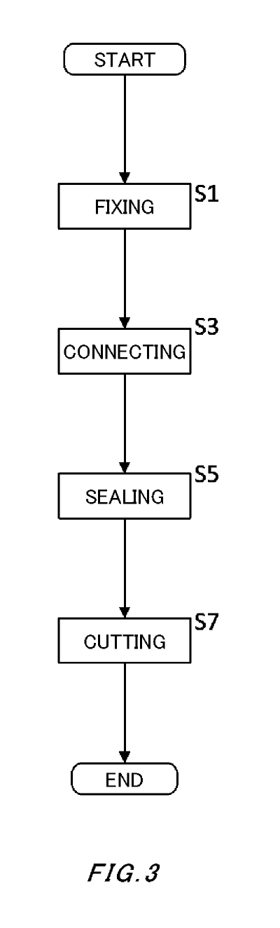

Subsequently, a method for manufacturing the semiconductor device 100 will be described. FIG. 3 is a diagram showing a method for manufacturing the semiconductor device 100 according to this embodiment.

As shown in this diagram, to manufacture the semiconductor device 100, at first, relative positions of electrodes 1210, 1211 of the first electrode pair 121 are fixed (step S1: fixing step). For example, relative to the first conductor 1215 (as one example, the leadframe segment 1111) including one electrode 1211, a position of the semiconductor chip 101 provided with the other electrode 1210 may be fixed. Specifically, in a state in which the semiconductor chip 101 is arranged on the leadframe body 1110 via the solder 112, the leadframe body 1110 may be arranged in the vicinity of the first conductor 1215 and both may be fixed by a jig. Similarly, relative positions of electrodes of the second electrode pair 122 to the fourth electrode pair 124 may be fixed, respectively. To arrange the semiconductor chip 101 on the leadframe body 1110, after heating the leadframe body 1110 with a heater in advance, the solder 112 and the semiconductor chip 101 may be sequentially arranged on the leadframe body 1110, then the semiconductor chip 101 and the leadframe body 1110 may be bonded via the solder 112. Alternatively, the semiconductor chip 101 and the leadframe body 1110 may also be bonded after the solder 112 and the semiconductor chip 101 are sequentially arranged on the leadframe body 1110, and then by heating these in a reflow furnace. When the leadframe 111 or the like is heated in the fixing step, cooling may be performed before performing a connecting process described later.

Next, the plurality of bonding wires 1310 of the first wire group 131 connect the electrodes 1210, 1211 of the first electrode pair 121 electrically in parallel (step S3: connecting step). For example, each bonding wire 1310 may be wired such that length of each of the plurality of bonding wires 1310 on the far side in the first direction Y is longer than length of each of the bonding wires 1310 on the near side, and each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. Also, bonding wires 1310 adjacent to each other among the plurality of bonding wires 1310 may have a shape such that the bonding wire 1310 on the near side of the first direction Y can fall down under the adjacent bonding wire 1310 on the far side of the first direction Y.

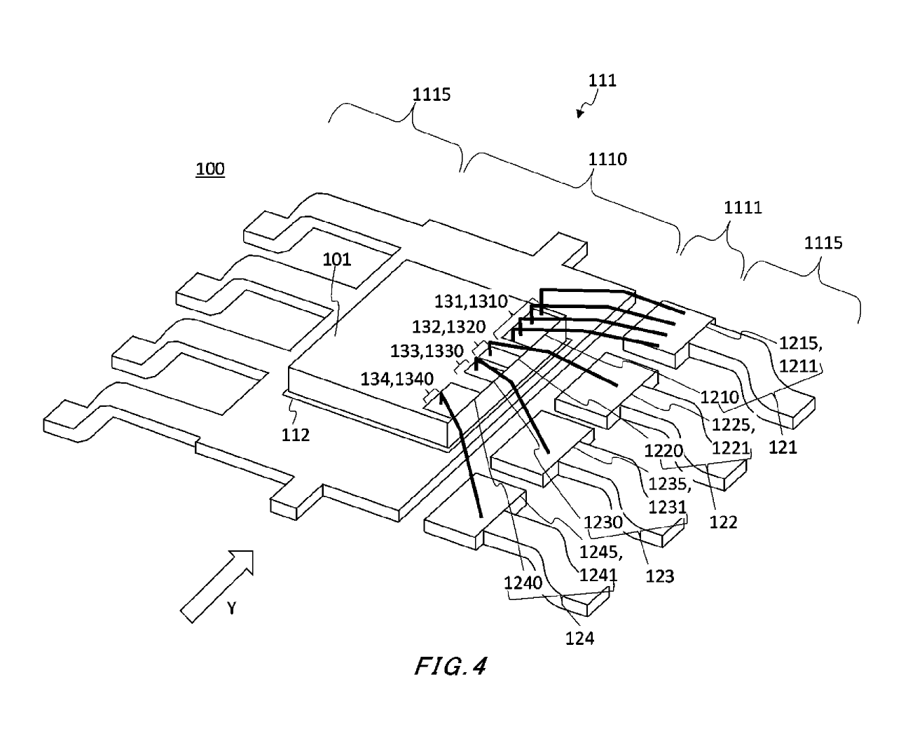

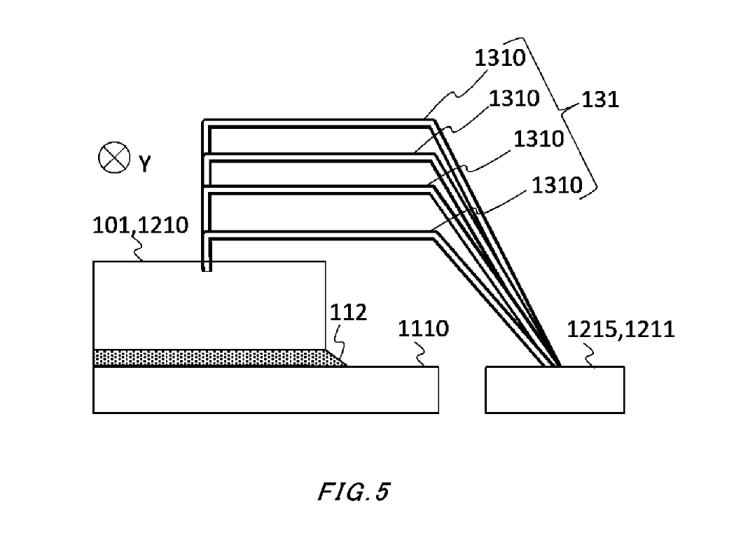

However, as described in detail further later using FIGS. 4 and 5, a shape of each bonding wire 1310 when being wired may be different from the shape after being sealed, that is, the shape of the bonding wire 1310 inside the semiconductor device 100.

Note that in this embodiment, as one example, the electrodes 1210, 1211 of the first electrode pair 121 are wire-bonded only by the plurality of bonding wires 1310 of the first wire group 131, and may be further wire-bonded by wire different from the bonding wires 1310.

In step S3 described above, the second wire group 132 to the fourth wire group 134 may further electrically connect electrodes of the second electrode pair 122 to electrodes of the fourth electrode pair 124, respectively.

Next, A molding material is injected into a molding mold (not shown) housing the semiconductor chip 101, the leadframe 111, the first electrode pair 121 to fourth electrode pair 124, the first wire group 131 to the fourth wire group 134 or the like from a first direction Y, and sealing these (step S5: sealing step). Thus, a molding material flows into gaps inside the forming mold, for example, gaps between the leadframe body 1110 and the leadframe segment 1111, peripheral regions of the bonding wires 1310 to 1340, or the like. And, as a result of each part of the bonding wires 1310 being pressed to the far side of the first direction Y by the molding material that flows from the near side toward the far side of the first direction Y inside the forming mold, the loop shape of each bonding wire 1310 extends in the first direction Y, and the bonding wires 1310 are wired such that each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. For example, the plurality of bonding wires 1310 of the first wire group 131 may be tilted toward the far side of the first direction Y, and may be wired such that heights of the plurality of bonding wires 1310 relative to the semiconductor chip 101 surface increase stepwise from the near side toward the far side in the first direction Y. Also, a difference in loop height between adjacent bonding wires 1310 among the plurality of bonding wires 1310 of the first wire group 131 may be equal to or greater than half of the diameter of the bonding wires 1310.

Next, an injecting point of the molding material in the sealing portion 140 at which mold-sealing has been performed in step S5 is cut (step S7: cutting step). For example, the molding material solidified in step S5 may be taken out of the forming mold, and the molding material solidified at the gate portion of the forming mold may be cut and removed. The injection trace 1400 is thus formed. Also, when there is a suction port for evacuating in the forming mold, a discharge trace may be formed by cutting and removing the molding material solidified at the suction port. The semiconductor device 100 is thus manufactured. Note that before or after the cutting step, a solder dipping process, a plating process may be performed on the external terminal 1115.

According to the method for manufacturing described above, the plurality of bonding wires 1310, which connect the first electrode pair 121 in parallel, are wired such that length of each of the bonding wires 1310 on the far side in the first direction Y that is parallel with the in-plane direction of the semiconductor chip 101 is longer than length of each of the bonding wires 1310 on the near side, and each height at respective positions of each of the bonding wires 1310 on the far side in the first direction Y is not lower than each height at respective positions, corresponding to the respective positions of each of the bonding wires 1310 on the far side, of each of the bonding wires 1310 on the near side. Thus, even in a case when the bonding wire 1310 is tilted toward the side of the adjacent bonding wire 1310 along the first direction Y by injecting the molding material into the forming mold from the first direction Y, it is possible to prevent bonding wires 1310 from coming into contact with each other, and to maintain the operating characteristics.

Also, because bonding wires 1310 adjacent to each other among the plurality of bonding wires 1310 have a shape such that the bonding wire 1310 on the near side in the first direction Y can fall down under the bonding wire 1310 on the far side, when the molding material is injected, the bonding wire on the near side enters below the bonding wire 1310 on the far side without coming into contact with it. Thus, it is possible to surely prevent adjacent bonding wires 1310 from coming into contact with each other.

Also, in the fixing step of step S1, because the position of the semiconductor chip 101 including the electrode 1210 is fixed relative to the first conductor 1215 including the electrode 1211 of the first electrode pair 121, it is possible to connect electrodes 1210, 1211 included in separate members easily. Also, because the electrode 1210 of the first electrode pair 121 is provided in the semiconductor chip 101 and the electrode 1211 is provided in the first conductor 1215, the operating characteristics tend to vary due to the contact of bonding wires 1310 with each other. Even in such a case, because it is possible to prevent bonding wires 1310 from coming into contact with each other by connecting the first electrode pair 121 in parallel by the plurality of bonding wires 1310 as described above, the operating characteristics can be maintained.

FIG. 4 is a diagram showing the semiconductor device 100 in a state where a connecting step is performed. A shape of each bonding wire 1310 of the first wire group 131 in a wired state may be different from the shape after being sealed by the sealing portion 140, that is, the shape of the bonding wire 1310 described in FIGS. 1 and 2. For example, the bonding wire 1310 may be bent at one or more points, and as a whole it may have a convex shape on a side being separated from the semiconductor chip 101. Also, as long as length of each of the plurality of bonding wires 1310 on the far side in the first direction Y is longer than length of each of the bonding wires 1310 on the near side, the plurality of bonding wires 1310 in the wired state may not be such that each height at respective positions of each of the bonding wires 1310 on the far side in the first direction Y is not lower than each height at respective positions, corresponding to the respective positions of each of the bonding wires 1310 on the far side, of each of the bonding wires 1310 on the near side.

Similarly, a shape of each bonding wire 1320 to 1340 of the second wire group 132 to the fourth wire group 134 in the wired state may be different from the shape after being sealed by the sealing portion 140, that is, the shape of the bonding wire 1310 described in FIGS. 1 and 2. For example, each shape of each bonding wire 1320 to 1340 may be a shape similar to that of the bonding wire 1310.

FIG. 5 is a diagram showing one example of the plurality of bonding wires 1310 of the first wire group 131 when the semiconductor device 100 in the state where the connecting step is performed is seen from the near side of the first direction Y.

In this diagram as one example, the plurality of bonding wires 1310 are bent at two points, and the middle part between the bend points is approximately parallel to the surface of the semiconductor chip 101. Also, the plurality of bonding wires 1310 are wired such that length of each of the bonding wires 1310 on the far side in the first direction Y that is parallel with the in-plane direction of the semiconductor chip 101 is longer than length of each of the bonding wires 1310 on the near side, and each height at respective positions of each of the bonding wires 1310 on the far side in the first direction Y is not lower than each height at respective positions, corresponding to the respective positions of each of the bonding wires 1310 on the far side, of each of the bonding wires 1310 on the near side.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

As will be apparent from the above description, according to (some) embodiment(s) of the present invention, both electrodes can be connected in parallel by a plurality of wires when flowing a large current between the same electrode pair.

What is claimed is:

1. A semiconductor device comprising;
a semiconductor chip,
a first electrode pair,
a first wire group that has a plurality of bonding wires that connect electrodes of the first electrode pair electrically in parallel, and
a sealing portion that mold-seals the semiconductor chip, the first electrode pair, and the first wire group, wherein
the plurality of bonding wires belonging to the first wire group are wired such that length of each of the bonding wires on a far side in a first direction that is parallel with an in-plane direction of the semiconductor chip is longer than length of each of the bonding wires on a near side, and each height at respective positions of each of the bonding wires on the far side in the first direction is not lower than each height at respective positions, corresponding to the respective positions of each of the bonding wires on the far side, of each of the bonding wires on the near side.

2. The semiconductor device according to claim 1 comprising a first conductor including one electrode of the first electrode pair, wherein
an other electrode of the first electrode pair is provided in the semiconductor chip.

3. The semiconductor device according to claim 1, wherein
the plurality of bonding wires belonging to the first wire group are wired such that heights of the plurality of bonding wires relative to the semiconductor chip surface increase stepwise from the near side toward the far side in the first direction.

4. The semiconductor device according to claim 1, wherein
a difference in loop height between adjacent bonding wires among the plurality of bonding wires belonging to the first wire group is equal to or greater than half of a diameter of the bonding wires.

5. The semiconductor device according to claim 1, wherein
at least one bonding wire of the plurality of bonding wires belonging to the first wire group is tilted toward the far side of the first direction.

6. The semiconductor device according to claim 1, further comprising a leadframe integrally including one electrode of the first electrode pair and an external terminal exposed to outside of the sealing portion.

7. The semiconductor device according to claim 6, wherein
an other electrode of the first electrode pair is a power supply electrode or a ground electrode of the semiconductor chip.

8. The semiconductor device according to claim 1, wherein
the sealing portion has an injection trace of a molding material at an end part on the near side of the first direction.

9. The semiconductor device according to claim 1, wherein
electrodes of the first electrode pair are wire-bonded only by the plurality of bonding wires belonging to the first wire group.

10. The semiconductor device according to claim 1 comprising;
a second electrode pair, and
a second wire group that has a plurality of bonding wires that connect electrodes of the second electrode pair electrically in parallel, wherein
the plurality of bonding wires belonging to the second wire group are wired such that length of each of the bonding wires on the far side in the first direction is longer than length of each of the bonding wires on the near side, and each height at respective positions of each of the bonding wires on the far side in the first direction is not lower than each height at respective positions, corresponding to the respective positions of each of the bonding wires on the far side, of each of the bonding wires on the near side.

11. A method for manufacturing semiconductor device comprising;
a fixing in which relative positions of electrodes of a first electrode pair are fixed,
a connecting in which a first wire group including a plurality of bonding wires connects electrodes of the first electrode pair electrically in parallel, and
a sealing in which a molding material is injected into a molding mold housing a semiconductor chip, the first electrode pair, and the first wire group from a first direction and sealing them, wherein
the plurality of bonding wires belonging to the first wire group are wired such that length of each of the bonding wires on a far side in a first direction is longer than length of each of the bonding wires on a near side, and each height at respective positions of each of the bonding wires on the far side in the first direction is not lower than each height at respective positions, corresponding to the respective positions of each of the bonding wires on the far side, of each of the bonding wires on the near side.

12. The method for manufacturing semiconductor device according to claim 11, wherein
bonding wires adjacent to each other among the plurality of bonding wires belonging to the first wire group have a shape such that the bonding wire on the near side of the first direction can fall down under the adjacent bonding wire on the far side of the first direction.

13. The method for manufacturing semiconductor device according to claim 11, further comprising a cutting that cuts an injecting point of the molding material in a sealing portion at which mold-sealing has been performed in the sealing.
